(19) United States
(12) Patent Application Publication
(10) Pub. No.: US 2025/0194115 A1
(43) Pub. Date: Jun. 12, 2025

(54) ISOLATOR

(71) Applicants: KABUSHIKI KAISHA TOSHIBA, Tokyo (JP); Toshiba Electronic Devices & Storage Corporation, Tokyo (JP)

(72) Inventor: Jia LIU, Yokohama Kanagawa (JP)

(73) Assignees: KABUSHIKI KAISHA TOSHIBA, Tokyo (JP); Toshiba Electronic Devices & Storage Corporation, Tokyo (JP)

(21) Appl. No.: 18/814,716

(22) Filed: Aug. 26, 2024

(30) Foreign Application Priority Data
Dec. 6, 2023 (JP) 2023-205937

(51) Int. Cl. H01L 23/495; H01L 23/00; H01L 23/31; H01L 25/16

(52) U.S. Cl. CPC H10D 1/20; H01L 23/49575; H01L 25/162; H01L 23/3107; H01L 24/32; H01L 24/48; H01L 24/73; H01L 2224/32245; H01L 2224/48175; H01L 2224/73265

(57) ABSTRACT

According to one embodiment, an isolator includes a first pad, a second pad, a first coil, an insulating layer, a third pad, a fourth pad, and a second coil. The first coil includes a first wiring and a second wiring. The first coil is coupled to the first pad and the second pad. The second coil includes a third wiring and a fourth wiring. The second coil is arranged to face the first coil with the insulating layer intervening therebetween. The second coil is coupled to the third pad and the fourth pad. The first wiring and the second wiring are coupled in parallel to each other between the first pad and the second pad. The third wiring and the fourth wiring are coupled in parallel to each other between the third pad and the fourth pad.

### CROSS-REFERENCE TO RELATED APPLICATIONS

This application is based upon and claims the benefit of priority from Japanese Patent Application No. 2023-205937, filed Dec. 6, 2023, the entire contents of which are incorporated herein by reference.

### FIELD

Embodiments described herein relate generally to an isolator.

### BACKGROUND

An isolator configured to transmit a signal from a transmission-side circuit to a reception-side circuit while they are isolated from each other is known.

### BRIEF DESCRIPTION OF THE DRAWINGS

FIG. 1 is a plan view showing an example of a planar layout of an isolator according to a first embodiment.

FIG. 2 is a sectional view taken along line S1-S1 of FIG. 1 and showing an example of a sectional structure of the isolator according to the first embodiment.

FIG. 3 is a planar view showing an example of a planar layout of a primary circuit within a wiring board included in the isolator according to the first embodiment.

FIG. 4 is a diagram illustrating cancellation of a magnetic flux caused by a phase shift between currents flowing through two wirings.

FIG. 5 is a planar view showing an example of a planar layout of a secondary circuit within the wiring board included in the isolator according to the first embodiment.

FIG. 6 is a perspective view showing an example of a structure of the wiring board included in the isolator according to the first embodiment.

FIG. 7 is a sectional view taken along line S2-S2 of FIG. 6 and showing an example of a sectional structure of the wiring board included in the isolator according to the first embodiment.

FIG. 8 is a sectional view taken along line S3-S3 of FIG. 6 and showing an example of a sectional structure of the wiring board included in the isolator according to the first embodiment.

FIG. 9 is a planar view showing an example of a planar layout of a primary circuit within a wiring board included in an isolator according to a second embodiment.

FIG. 10 is a planar view showing an example of a planar layout of a secondary circuit within the wiring board included in the isolator according to the second embodiment.

FIG. 11 is a perspective view showing an example of a structure of the wiring board included in the isolator according to the second embodiment.

FIG. 12 is a sectional view taken along line S4-S4 of FIG. 11 and showing an example of a sectional structure of the wiring board included in the isolator according to the second embodiment.

FIG. 13 is a sectional view taken along line S5-S5 of FIG. 11 and showing an example of a sectional structure of the wiring board included in the isolator according to the second embodiment.

FIG. 14 is a sectional view taken along line S6-S6 of FIG. 11 and showing an example of a sectional structure of the wiring board included in the isolator according to the second embodiment.

FIG. 15 is a plan view showing an example of a planar layout of an isolator according to a modification of the second embodiment.

FIG. 16 is a sectional view taken along line S7-S7 of FIG. 15 and showing an example of a sectional structure of the isolator according to the modification of the second embodiment.

FIG. 17 is a sectional view taken along line S8-S8 of FIG. 15 and showing an example of a sectional structure of the isolator according to the modification of the second embodiment.

FIG. 18 is a planar view showing an example of a planar layout of a primary circuit within a wiring board included in the isolator according to the modification of the second embodiment.

FIG. 19 is a planar view showing an example of a planar layout of a secondary circuit within the wiring board included in the isolator according to the modification of the second embodiment.

FIG. 20 is a perspective view showing an example of a structure of the wiring board included in the isolator according to the modification of the second embodiment.

FIG. 21 is a sectional view taken along line S9-S9 of FIG. 20 and showing an example of a sectional structure of the wiring board included in the isolator according to the modification of the second embodiment.

FIG. 22 is a sectional view taken along line S10-S10 of FIG. 20 and showing an example of a sectional structure of the wiring board included in the isolator according to the modification of the second embodiment.

FIG. 23 is a sectional view taken along line S11-S11 of FIG. 20 and showing an example of a sectional structure of the wiring board included in the isolator according to the modification of the second embodiment.

FIG. 24 is a planar view showing an example of a planar layout of a primary circuit within a wiring board included in an isolator according to a modification of the first embodiment.

FIG. 25 is a planar view showing an example of a planar layout of a secondary circuit within the wiring board included in the isolator according to the modification of the first embodiment.

FIG. 26 is a perspective view showing an example of a structure of the wiring board included in the isolator according to the modification of the first embodiment.

FIG. 27 is a sectional view taken along line S12-S12 of FIG. 26 and showing an example of a sectional structure of the wiring board included in the isolator according to the modification of the first embodiment.

FIG. 28 is a sectional view taken along line S13-S13 of FIG. 26 and showing an example of a sectional structure of the wiring board included in the isolator according to the modification of the first embodiment.

FIG. 29 is a sectional view taken along line S14-S14 of FIG. 26 and showing an example of a sectional structure of the wiring board included in the isolator according to the modification of the first embodiment.

### DETAILED DESCRIPTION

In general, according to one embodiment, an isolator includes a first pad, a second pad, a first coil, an insulating layer, a third pad, a fourth pad, and a second coil. The first coil includes a first wiring and a second wiring. The first coil is coupled to the first pad and the second pad. The second coil includes a third wiring and a fourth wiring. The second coil is arranged to face the first coil with the insulating layer intervening between the second coil and the first coil. The second coil is coupled to the third pad and the fourth pad. The first wiring and the second wiring are coupled in parallel to each other between the first pad and the second pad. The third wiring and the fourth wiring are coupled in parallel to each other between the third pad and the fourth pad.

Hereinafter, an embodiment will be described with reference to the accompanying drawings. The dimensions and ratios in the drawings are not always the same as the actual ones. In the following description, constituent elements having substantially the same function and configuration will be assigned the same reference symbol, and repeat descriptions may be omitted. In the case where elements having similar configurations are distinguished from each other in particular, their identical reference symbols may be assigned different letters or numbers. All of the descriptions of an embodiment are applicable as descriptions of another embodiment, unless explicitly or self-evidently excluded.

### 1. First Embodiment

An isolator according to a first embodiment will be described. The following will describe an example of a digital isolator, which is configured to transmit a signal from a transmission-side circuit to a reception-side circuit while they are isolated from each other, through magnetic connection between a coil coupled to the transmission-side circuit and a coil coupled to the reception-side circuit.

### 1.1 Structure of Isolator

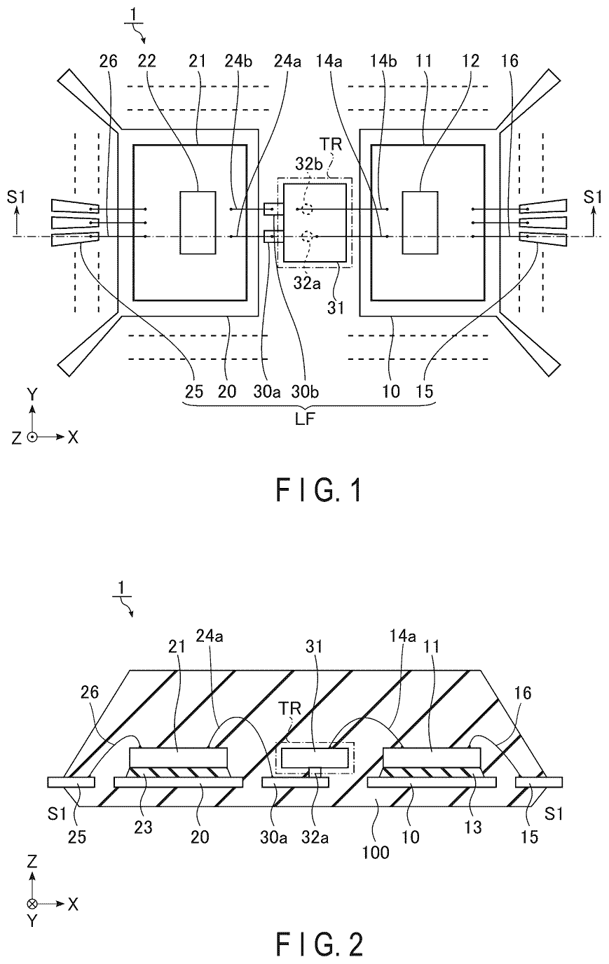

A structure of an isolator will be described with reference to FIG. 1 and FIG. 2. FIG. 1 is a planar view showing an example of a planar layout of the isolator. FIG. 2 is a sectional view taken along line S1-S1 of FIG. 1 and showing an example of a sectional structure of the isolator.

An isolator 1 is, for example, a semiconductor package. As shown in FIG. 1 and FIG. 2, the isolator 1 includes die pads 10 and 20, semiconductor chips 11 and 21, leads 15 and 25, frames 30a and 30b, a transformer TR, and an insulating member 100. FIG. 1 omits illustration of the insulating member 100.

The die pads 10 and 20 are members for supporting the semiconductor chips. The die pad 10 supports the semiconductor chip 11. The die pad 20 supports the semiconductor chip 21.

The leads 15 and 25 are members for coupling the semiconductor chips and external wirings. The isolator 1 includes a plurality of leads 15 and a plurality of leads 25. Each lead 15 couples the semiconductor chip 11 to an external wiring via a bonding wire 16. The number of bonding wires 16 is equal to the number of leads 15. Each lead 25 couples the semiconductor chip 21 to an external wiring via a bonding wire 26. The number of bonding wires 26 is equal to the number of leads 25.

The frames 30a and 30b are members for coupling the semiconductor chip 21 and the transformer TR while supporting the transformer TR. The frame 30a couples the semiconductor chip 21 to the transformer TR via a bonding wire 24a and a via 32a. The frame 30b couples the semiconductor chip 21 to the transformer TR via a bonding wire 24b and a via 32b.

The die pads 10 and 20, the leads 15 and 25, and the frames 30a and 30b constitute a lead frame. Hereinafter, a combination of the die pads 10 and 20, the leads 15 and 25, and the frames 30a and 30b will be referred to as a “lead frame LF”. The lead frame LF is formed into, for example, a plate shape. The lead frame LF is formed of a conductive material. The lead frame LF include, for example, a metal material.

Hereinafter, a plane parallel to a surface of the lead frame LF will be referred to as an “XY surface”. On the XY plane, directions perpendicularly intersecting each other will be referred to as an “X direction” and a “Y direction”. A direction intersecting the XY plane will be referred to as a “Z direction”. In the Z direction, a direction extending from the lead frame LF to the semiconductor chips 11 and 21 will be referred to as an “upper direction”.

As shown in FIG. 1, the die pads 10 and 20 are spaced apart from each other in the X direction. The frames 30a and 30b are spaced apart from each other in the Y direction. The frames 30a and 30b are arranged between the die pad 10 and the die pad 20, and are apart from the die pads 10 and 20 in the X direction. The plurality of leads 15 are spaced apart from each other in the Y direction. The plurality of leads 15 are arranged on the opposite side to a side on which the frames 30a and 30b of the die pad 10 are arranged in the X direction, and are apart from the die pad 10. The plurality of leads 25 are spaced apart from each other in the Y direction. The plurality of leads 25 are arranged on the opposite side to a side on which the frames 30a and 30b of the die pad 20 are arranged in the X direction, and are apart from the die pad 20.

Each of the semiconductor chips 11 and 21 is, for example, an integrated circuit (IC) chip. The semiconductor chips 11 and 21 are spaced apart from each other in the X direction.

The semiconductor chip 11 includes a circuit 12. The circuit 12 includes a signal transmission/reception circuit and a signal modulation/demodulation circuit. The circuit 12 is coupled to a bonding wire 14a via wiring (not shown) within the semiconductor chip 11. The circuit 12 is coupled to a bonding wire 14b via wiring (not shown) within the semiconductor chip 11. The circuit 12 is coupled to a bonding wire 16 via wiring (not shown) within the semiconductor chip 11.

The semiconductor chip 21 includes a circuit 22. The circuit 22 includes a signal transmission/reception circuit and a signal modulation/demodulation circuit. The circuit 22 is coupled to a bonding wire 24a via wiring (not shown) within the semiconductor chip 21. The circuit 22 is coupled to a bonding wire 24b via wiring (not shown) within the semiconductor chip 21. The circuit 22 is coupled to a bonding wire 26 via wiring (not shown) within the semiconductor chip 21.

The transformer TR is, for example, an insulation transformer. The transformer TR is arranged between the semiconductor chip 11 and the semiconductor chip 21 in the X direction, and is apart from the semiconductor chips 11 and 21.

The transformer TR includes, for example, a wiring board 31. The wiring board 31 is, for example, a flexible printed circuit (FPC) having flexibility. The wiring board 31 is formed into, for example, a plate shape.

The board 31 includes, for example, a primary circuit FC, an insulating layer, and a secondary circuit SC to be described later. The primary circuit FC includes a coil CL1 to be described later. The secondary circuit SC includes a coil CL2 to be described later. The wiring board 31 is configured to transmit a signal from the circuit 12 to the circuit 22 or from the circuit 22 to the circuit 12 in a state in which the circuit 12 within the semiconductor chip 11 and the circuit 22 within the semiconductor chip 21 are isolated from each other using the coils CL1 and CL2. The wiring board 31 will be described later in detail.

In a case where a signal is transmitted from the circuit 12 to the circuit 22, the circuit 12 functions as a transmission-side circuit and the circuit 22 functions as a reception-side circuit. On the other hand, in a case where a signal is transmitted from the circuit 22 to the circuit 12, the circuit 22 functions as the transmission-side circuit and the circuit 12 functions as the reception-side circuit.

The insulating member 100 includes, for example, an insulating resin. The die pads 10 and 20, the semiconductor chips 11 and 21, the bonding wires 14a, 14b, 16, 24a, 24b, and 26, the frames 30a and 30b, the wiring board 31, and the vias 32a and 32b are sealed with the insulating member 100.

As shown in FIG. 2, the semiconductor chip 11 is provided on the die pad 10 with an adhesive member 13 intervening therebetween. One end of the bonding wire 14a and one end of the bonding wire 16 are provided on the semiconductor chip 11.

The other end of the bonding wire 16 is provided on the lead 15.

The semiconductor chip 21 is provided on a die pad 20 with an adhesive member 23 intervening therebetween. One end of the bonding wire 24a and one end of the bonding wire 26 are provided on the semiconductor chip 21.

The other end of the bonding wire 26 is provided on the lead 25.

The other end of the bonding wire 24a is provided on the frame 30a. The via 32a is provided on the frame 30a. The wiring board 31 is provided on the via 32a. The other end of the bonding wire 14a is provided on the wiring board 31.

The die pads 10 and 20, the semiconductor chips 11 and 21, the adhesive members 13 and 23, the bonding wires 14a, 16, 24a, and 26, a part of the lead 15, a part of the lead 25, the frame 30a, the wiring board 31, and the via 32a are covered with the insulating member 100. Each of the leads 15 and 25 is fixed by the insulating member 100 and has a portion exposed to the outside of the insulating member 100.

Meanwhile, a sectional structure in the plane including the bonding wires 14b and 24b and the via 32b is similar to that in the plane including the bonding wires 14a and 24a and the via 32a shown in FIG. 2. Specifically, one end of the bonding wire 14b is provided on the semiconductor chip 11. One end of the bonding wire 24b is provided on the semiconductor chip 21. The other end of the bonding wire 24b is provided on the frame 30b. Furthermore, the via 32b is provided on the frame 30b. The wiring board 31 is provided on the via 32b. The other end of the bonding wire 14b is provided on the wiring board 31.

### 1.2 Structure of Wiring Board

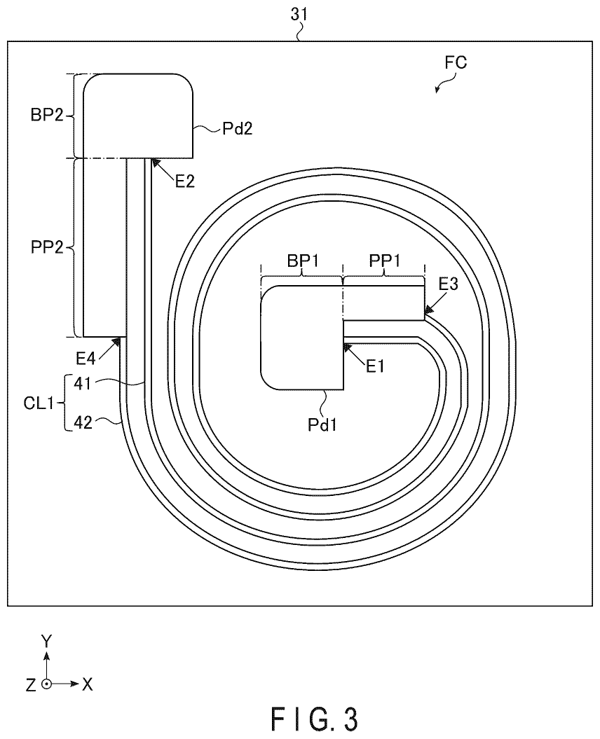

A structure of the wiring board 31 will be described with reference to FIG. 3 and FIG. 5 to FIG. 8.

FIG. 3 is a planar view showing an example of a planar layout of the primary circuit FC within the wiring board 31. As shown in FIG. 3, the wiring board 31 includes pads Pd1 and Pd2 and the coil CL1. FIG. 3 omits illustration of the secondary circuit SC and the insulating layer within the wiring board 31.

The pad Pd1 is a member for coupling the coil CL1 and the bonding wire 14a. The pad Pd2 is a member for coupling the coil CL1 and the bonding wire 14b. The pad Pd1 includes a base portion BP1 and a projection portion PP1 projecting from the base portion BP1. The projection portion PP1 projects from the base portion BP1 in the X direction. More specifically, the projection portion PP1 projects from the base portion BP1 to the opposite side to the pad Pd2. The pad Pd2 includes a base portion BP2 and a projection portion PP2 projecting from the base portion BP2. The projection portion PP2 projects from the base portion BP2 in the Y direction. More specifically, the projection portion PP2 projects from the base portion BP2 to the pad Pd1 side. As described above, the pads Pd1 and Pd2 are formed into, for example, a substantially L shape when viewed from a top (when viewed from the top of the drawing sheet). The pads Pd1 and Pd2 are formed of a conductive material.

The coil CL1 includes a wiring 41 and a wiring 42.

The wiring 41 includes a first end E1 and a second end E2. The first end E1 is coupled to the base portion BP1 of the pad Pd1. The second end E2 is coupled to the base portion BP2 of the pad Pd2. The wiring 41 is formed into, for example, a spiral shape extending from the first end E1 in a clockwise rotation direction to the outside when viewed from the top.

The wiring 42 includes a third end E3 and a fourth end E4. The third end E3 is coupled to the projection portion PP1 of the pad Pd1. The fourth end E4 is coupled to the projection portion PP2 of the pad Pd2. The wiring 42 is apart from the wiring 41 and is formed into, for example, a spiral shape extending from the third end E3 in a clockwise rotation direction to the outside when viewed from the top.

The wirings 41 and 42 are formed of a conductive material. The wirings 41 and 42 include, for example, copper.

With the structure described above, the coil CL1 is coupled to the pads Pd1 and Pd2. More specifically, in the present embodiment, the wirings 41 and 42 are coupled in parallel to each other between the pad Pd1 and the pad Pd2.

Furthermore, in the present embodiment, the wirings 41 and 42 are designed to be equal in terms of size and design rule (line and space) to a coil CL1 constituted by a single wiring.

In a case of the wiring 41 and 42 thus designed, their spiral shape is formed into, for example, an ellipsoidal shape. That is, the coil CL1 is formed such that its outer diameter in the Y direction is greater than its outer diameter in the X direction. Meanwhile, the spiral shape of the wirings 41 and 42 may be, for example, a rectangular shape or a polygonal shape.

Furthermore, in the Y direction, the coil CL1 is formed such that the total number (2 in the example shown in FIG. 3) of turns in the wirings 41 and 42 on the side close to the pad Pd2 with respect to the pad Pd1 is smaller than the total number (3 in the example shown in FIG. 3) of turns in the wirings 41 and 42 on the opposite side to the pad Pd2 with respect to the pad Pd1. Therefore, the sum of the length of the wiring 41 and the length of the wiring 42 is smaller than the length of the wiring of the coil CL1 constituted by the single wiring. Meanwhile, the sum of the length of the wiring 41 and the length of the wiring 42 may be equal to the length of the wiring of the coil CL1 constituted by the single wiring.

Furthermore, the present embodiment is designed such that the wiring 42 is equal in electrical length to the wiring 41. That is, a relationship between the electrical length of the wiring 42 and the electrical length of the wiring 41 is expressed below by Equation (1).

$$Electrical Length of Wiring 42 = Electrical Length of Wiring 41 \qquad ( 1 )$$

The electrical length is a length calculated based on a speed of a current propagating through an inside of a wiring. The speed of the current propagating through the inside of the wiring is calculated based on non-permittivity and non-permeability of the wiring. The speed of the current propagating through the inside of the wiring is lower than a speed of a current through a vacuum. A wavelength of the current propagating through the inside of the wiring is shorter than a wavelength of the current through the vacuum. For example, in a case where the current propagating through the inside of the wiring has a wavelength of 50 [cm], a ¼ wavelength is 12.5 [cm] and a ¼ electrical length is about 6 [cm].

Herein, a power efficiency of the transformer TR will be described. The power efficiency of the transformer TR depends on a product of a coupling coefficient k and a Q value. The power efficiency of the transformer TR affects the power efficiency of the isolator 1.

The coupling coefficient k is a value indicative of a degree of coupling between two coils constituting the transformer TR. The coupling coefficient k is expressed below by Equation (2).

$$k = M / √ ( L 1 \times L 2 ) \qquad ( 2 )$$

In Equation (2) above, M represents a mutual inductance. L1 represents a self-inductance of one coil. L2 represents a self-inductance of the other coil.

The Q value is a value indicative of a quality of a coil. As the Q value increases, a loss to a high frequency decreases. The Q value is expressed below by Equation (3).

$$Q = ω L / R \qquad ( 3 )$$

In Equation (3) above, ω represents a frequency of a current. L represents a self-inductance of a coil. R represents a resistance of a coil.

According to Equation (3) above, as the resistance R of the coil decreases, the Q value increases. As described above, the power efficiency of the transformer TR depends on the product of the coupling coefficient k and the Q value. Thus, the power efficiency of the transformer TR increases as the Q value increases.

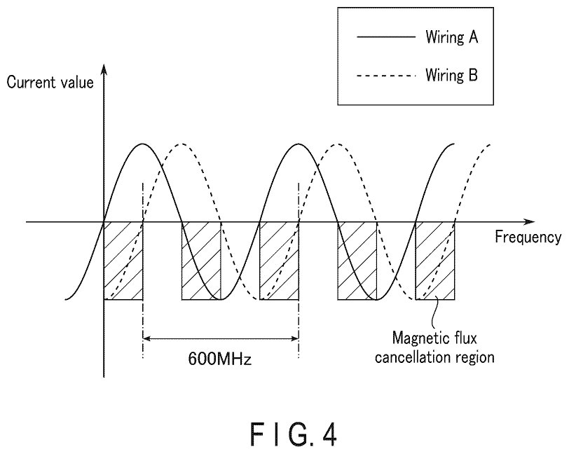

FIG. 4 is a diagram illustrating cancellation of a magnetic flux caused by a phase shift between currents flowing through two wirings. In FIG. 4, a waveform of a current flowing through one wiring is indicated by a solid line, and a waveform of a current flowing through the other wiring is indicated by a dashed line. Hereinafter, one wiring will also be referred to as a “wiring A”. The other wiring will also be referred to as a “wiring B”. The vertical axis represents a current value. The horizontal axis represents a frequency of a current. The example in FIG. 4 shows a state having a phase shift between a current flowing through the wiring A and a current flowing through the wiring B. Furthermore, FIG. 4 shows a case in which currents respectively flowing through the wirings A and B have a frequency of 600 [MHz].

As shown in FIG. 4, the occurrence of a phase shift between a current flowing through the wiring A and a current flowing through the wiring B causes cancellation of a magnetic flux ϕ1 generated by the current flowing through the wiring A and a magnetic flux ϕ2 generated by the current flowing through the wiring B. In the example in FIG. 4, a region in which cancellation of a magnetic flux is caused is indicated as a magnetic flux cancellation region with diagonal lines. In a case in which cancellation of a magnetic flux is caused, the sum of the magnetic flux ϕ1 and the magnetic flux ϕ2 becomes smaller than in a case in which cancellation of a magnetic flux is not caused.

With respect to a transformer in which two coils each including the wiring A and the wiring B are arranged to face each other, in the case in which the aforementioned cancellation of a magnetic flux is caused, the coupling coefficient k is smaller than in the case in which the aforementioned cancellation of a magnetic flux is not caused. As described above, the power efficiency of the transformer TR depends on the product of the coupling coefficient k and the Q value. Thus, the power efficiency of the transformer TR increases as the coupling coefficient k increases.

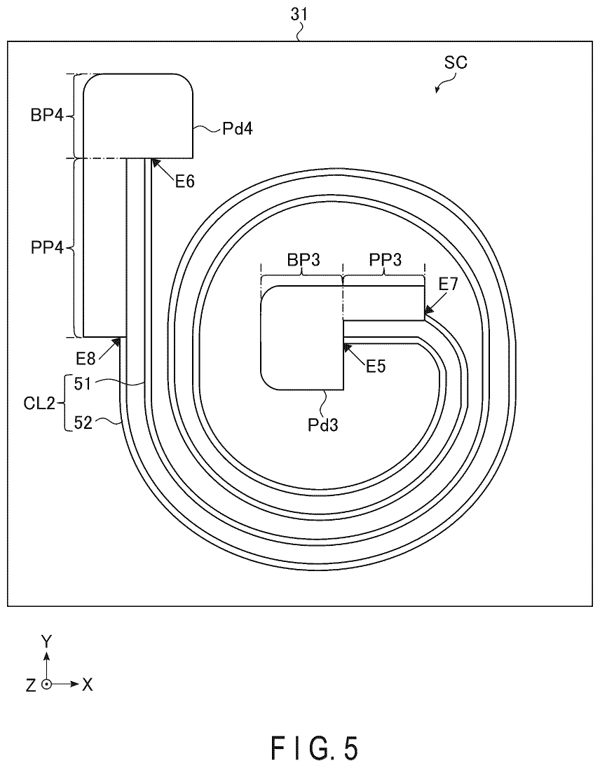

FIG. 5 is a planar view showing an example of a planar layout of the secondary circuit SC within the wiring board 31. As shown in FIG. 5, the wiring board 31 includes pads Pd3 and Pd4 and the coil CL2. FIG. 5 omits illustration of the primary circuit FC and the insulating layer within the wiring board 31.

The secondary circuit SC is similar in structure to the primary circuit FC. Details will be described below. The pad Pd3 is a member for coupling the coil CL2 and the via 32a. The pad Pd4 is a member for coupling the coil CL2 and the via 32b. The pad Pd3 includes a base portion BP3 and a projection portion PP3 projecting from the base portion BP3. The projection portion PP3 projects from the base portion BP3 in the X direction. More specifically, the projection portion PP3 projects from the base portion BP3 to the opposite side to the pad Pd4. The pad Pd4 includes a base portion BP4 and a projection portion PP4 projecting from the base portion BP4. The projection portion PP4 projects from the base portion BP4 in the Y direction. More specifically, the projection portion PP4 projects from the base portion BP4 to the pad Pd3 side. As described above, the pads Pd3 and Pd4 are formed into, for example, a substantially L shape when viewed from a top. The pads Pd3 and Pd4 are formed of a conductive material.

The coil CL2 includes a wiring 51 and a wiring 52.

The wiring 51 includes a fifth end E5 and a sixth end E6. The fifth end E5 is coupled to the base portion BP3 of the pad Pd3. The sixth end E6 is coupled to the base portion BP4 of the pad Pd4. The wiring 51 is formed into, for example, a spiral shape extending from the fifth end E5 in a clockwise rotation direction to the outside when viewed from the top.

The wiring 52 includes a seventh end E7 and an eighth end E8. The seventh end E7 is coupled to the projection portion PP3 of the pad Pd3. The eighth end E8 is coupled to the projection portion PP4 of the pad Pd4. The wiring 52 is apart from the wiring 51 and is formed into, for example, a spiral shape extending from the seventh end E7 in a clockwise rotation direction to the outside when viewed from the top.

The wirings 51 and 52 are formed of a conductive material. The wirings 51 and 52 include, for example, copper.

With the structure described above, the coil CL2 is coupled to the pads Pd3 and Pd4. More specifically, in the present embodiment, the wirings 51 and 52 are coupled in parallel to each other between the pad Pd3 and the pad Pd4.

Furthermore, in the present embodiment, the wirings 51 and 52 are designed to be equal in terms of size and design rule (line and space) to a coil CL2 constituted by a single wiring.

In a case of the wiring 51 and 52 thus designed, their spiral shape is formed into, for example, an ellipsoidal shape. That is, the coil CL2 is formed such that its outer diameter in the Y direction is greater than its outer diameter in the X direction. Meanwhile, the spiral shape of the wirings 51 and 52 may be, for example, a rectangular shape or a polygonal shape.

Furthermore, in the Y direction, the coil CL2 is formed such that the total number (2 in the example shown in FIG. 5) of turns in the wirings 51 and 52 on the side close to the pad Pd4 with respect to the pad Pd3 is smaller than the total number (3 in the example shown in FIG. 5) of turns in the wirings 51 and 52 on the opposite side to the pad Pd4 with respect to the pad Pd3. Therefore, the sum of the length of the wiring 51 and the length of the wiring 52 is smaller than the length of the wiring of the coil CL2 constituted by the single wiring. Meanwhile, the sum of the length of the wiring 51 and the length of the wiring 52 may be equal to the length of the wiring of the coil CL2 constituted by the single wiring.

Furthermore, the present embodiment is designed such that the wiring 52 is equal in electrical length to the wiring 51.

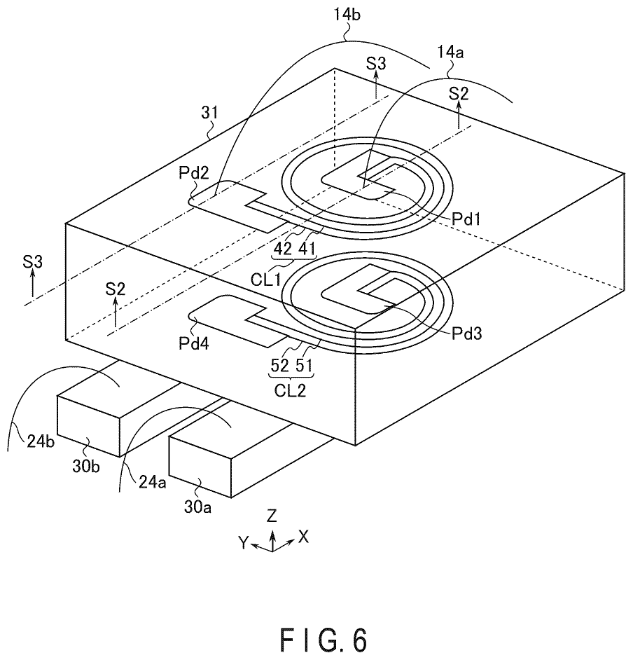

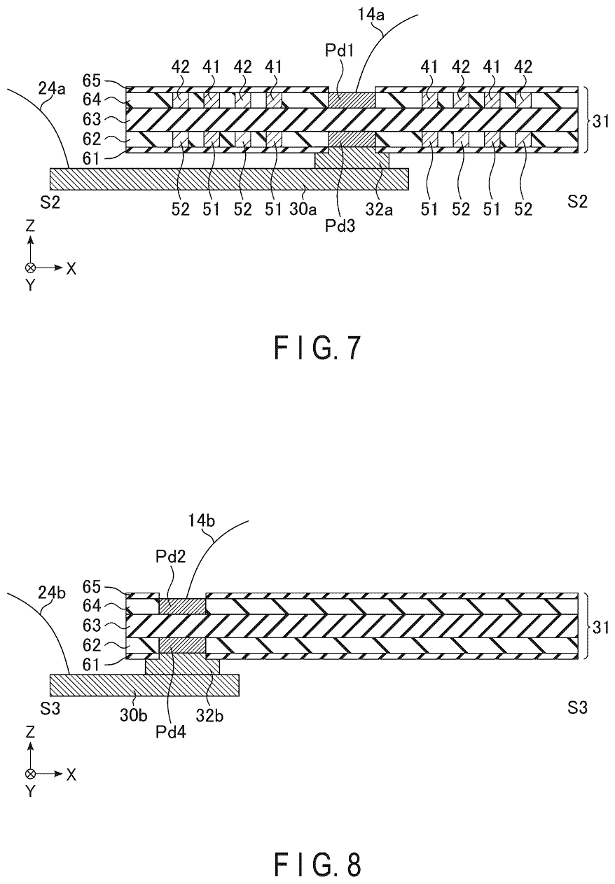

FIG. 6 is a perspective view showing an example of a structure of the wiring board 31. FIG. 7 is a sectional view taken along line S2-S2 of FIG. 6 and showing an example of a sectional structure of the wiring board 31. FIG. 8 is a sectional view taken along line S3-S3 of FIG. 6 and showing an example of a sectional structure of the wiring board 31.

As shown in FIG. 6 to FIG. 8, the wiring board 31 includes the pads Pd1 and Pd2, the coil CL1, the pads Pd3 and Pd4, the coil CL2, and insulating layers 61 to 65.

FIG. 6 to FIG. 8 also show the bonding wires 14a, 14b, 24a, and 24b, the frames 30a and 30b, and the vias 32a and 32b. FIG. 6 omits illustration of the vias 32a and 32b and the insulating layers 61 to 65.

As shown in FIG. 6, the coil CL1 is provided above the coil CL2 in the Z direction. That is, the coil CL1 is provided at a position at which it overlaps the coil CL2 in the Z direction. In other words, the coil CL2 is arranged so as to face the coil CL1 with the insulating layer 63 intervening therebetween. Meanwhile, in the example in FIG. 6, a set of the pads Pd1 and Pd2 and the coil CL1, and a set of the pads Pd3 and Pd4 and the coil CL2 are arranged in alignment with each other. However, these sets may be arranged in a rotating manner with each other. In other words, it suffices that the coil CL1 and the coil CL2 are arranged such that a magnetic flux which penetrates the coil CL1 penetrates the coil CL2 and such that a magnetic flux which penetrates the coil CL2 penetrates the coil CL1.

The pad Pd1 is coupled to the bonding wire 14a. The pad Pd2 is coupled to the bonding wire 14b. The semiconductor chip 11 is coupled to the coil CL1 via the bonding wires 14a and 14b and the pads Pd1 and Pd2.

The pad Pd3 is coupled to the bonding wire 24a via the via 32a and the frame 30a. The pad Pd4 is coupled to the bonding wire 24b via the via 32b and the frame 30b. The semiconductor chip 21 is coupled to the coil CL2 via the bonding wires 24a and 24b, the frames 30a and 30b, the vias 32a and 32b, and the pads Pd3 and Pd4.

As shown in FIG. 7 and FIG. 8, the wiring board 31 has a structure in which the insulating layers 61, 62, 63, 64, and 65 are stacked in this order.

As shown in FIG. 7, the insulating layer 61 includes an opening for coupling the pad Pd3 and the via 32a. The via 32a is provided within the opening of the insulating layer 61 and in the vicinity of the opening on the lower surface of the insulating layer 61. Furthermore, the via 32a is in contact with the upper surface of the frame 30a. The via 32a is formed of a conductive material. The bonding wire 24a is provided on the frame 30a.

The insulating layer 62 is provided on the insulating layer 61 and the via 32a. The pad Pd3 and the wirings 51 and 52 (the coil CL2) are provided within the insulating layer 62. In other words, the pad Pd3 and the wirings 51 and 52 are provided in the same layer. The pad Pd3 is provided on the via 32a. In other words, the pad Pd3 is in contact with the via 32a.

The insulating layer 63 is provided on the insulating layer 62, the pad Pd3, and the wirings 51 and 52.

The insulating layer 64 is provided on the insulating layer 63. The pad Pd1 and the wirings 41 and 42 (the coil CL1) are provided within the insulating layer 64. In other words, the pad Pd1 and the wirings 41 and 42 are provided in the same layer.

The insulating layer 65 is provided on the insulating layer 64 and the wirings 41 and 42. The insulating layer 65 includes an opening for coupling the pad Pd1 and the bonding wire 14a. The pad Pd1 is provided below the opening of the insulating layer 65. The bonding wire 14a is provided on the pad Pd1.

As shown in FIG. 8, the insulating layer 61 includes an opening for coupling the pad Pd4 and the via 32b. The via 32b is provided within the opening of the insulating layer 61 and in the vicinity of the opening on the lower surface of the insulating layer 61. Furthermore, the via 32b is in contact with the upper surface of the frame 30b. The via 32b is formed of a conductive material. The bonding wire 24b is provided on the frame 30b.

The insulating layer 62 is provided on the insulating layer 61 and the via 32b. The pad Pd4 is provided within the insulating layer 62. In other words, the pad Pd4 is provided in the same layer as the pad Pd3. The pad Pd4 is provided on the via 32b. In other words, the pad Pd4 is in contact with the via 32b.

The pad Pd2 is provided within the insulating layer 64. In other words, the pad Pd2 is provided in the same layer as the pad Pd1.

The insulating layer 65 includes an opening for coupling the pad Pd2 and the bonding wire 14b. The pad Pd2 is provided below the opening of the insulating layer 65. The bonding wire 14b is provided on the pad Pd2.

The isolator 1 according to the present embodiment can improve the power efficiency of the transformer TR.

In the transformer including two coils each constituted by a single wiring turned in a spiral shape, the single wiring becomes greater as the number of turns increases. Thus, a resistance of the single wiring (coil resistance) increases with a quadratic curve changing tendency. This decreases the Q value of the coils. The decrease of the Q value decreases the power efficiency of the transformer, too.

On the other hand, in the present embodiment, the isolator 1 includes the pads Pd1 and Pd2, the coil CL1, the insulating layer, the pads Pd3 and Pd4, and the coil CL2. The coil CL1 includes the wiring 41 and the wiring 42. The coil CL1 is coupled to the pads Pd1 and Pd2. The coil CL2 includes the wiring 51 and the wiring 52. The coil CL2 is arranged so as to face the coil CL1 with the insulating layer intervening therebetween. The coil CL2 is coupled to the pads Pd3 and Pd4.

The wirings 41 and 42 are coupled in parallel to each other between the pad Pd1 and the pad Pd2. In other words, the coil CL1 has a double wiring structure including the wirings 41 and 42. The wirings 51 and 52 are coupled in parallel to each other between the pad Pd3 and the pad Pd4. In other words, the coil CL2 has a double wiring structure including the wirings 51 and 52.

This decreases a combined resistance of the wirings 41 and 42 between the pad Pd1 and the pad Pd2 as compared to a case in which the wirings 41 and 42 are coupled in series between the pad Pd1 and the pad Pd2. This decreases a combined resistance of the wirings 51 and 52 between the pad Pd3 and the pad Pd4 as compared to a case in which the wirings 51 and 52 are coupled in series between the pad Pd3 and the pad Pd4.

Accordingly, the Q value of the coil CL1 increases as compared to a case in which the coil CL1 is constituted by a single wiring. The Q value of the coil CL2 increases as compared to a case in which the coil CL2 is constituted by a single wiring. By this, the present embodiment can improve the power efficiency of the transformer TR.

Furthermore, in the present embodiment, the sum of the length of the wiring 41 and the length of the wiring 42 is smaller than the length of the wiring of the coil CL1 constituted by the single wiring. In other words, the total number of turns in the wirings 41 and 42 included in the coil CL1 is smaller than the total number of turns in the wiring of the coil CL1 constituted by the single wiring. The sum of the length of the wiring 51 and the length of the wiring 52 is smaller than the length of the wiring of the coil CL2 constituted by the single wiring. In other words, the total number of turns in the wirings 51 and 52 included in the coil CL2 is smaller than the total number of turns in the wiring of the coil CL2 constituted by a single wiring. By this, a self-inductance of the coil CL1 decreases as compared to a case in which the coil CL1 is constituted by a single wiring. A self-inductance of the coil CL2 decreases as compared to a case in which the coil CL2 is constituted by a single wiring.

According to Equation (2) above, the coupling coefficient k decreases as the self-inductances L1 and L2 decrease. However, the increase amount of the Q value caused by the double wiring structure of the wirings 41 and 42 and the double wiring structure of the wirings 51 and 52 becomes greater than the decrease amount of the coupling coefficient k. Therefore, the present embodiment can improve the power efficiency of the transformer TR.

Furthermore, a resonance frequency of the coil CL1 increases as a self-inductance of the coil CL1 decreases. A resonance frequency of the coil CL2 increases as a self-inductance of the coil CL2 decreases. Therefore, the present embodiment increases a resonance frequency of the coil CL1 as compared to a case in which the coil CL1 is constituted by a single wiring. The coil CL2 increases in resonance frequency as compared to a case in which the coil CL2 is constituted by a single wiring. That is, the present embodiment can enlarge a frequency band of the transformer TR. Meanwhile, for example, in a case of the transformer TR whose operation frequency is set to 600 [MHz], it is preferable that a resonance frequency of the coils CL1 and CL2 be equal to or greater than 1800 [MHz], which is three times 600 [MHz].

Furthermore, in the present embodiment, an electrical length of the wiring 42 is equal to an electrical length of the wiring 41. The wiring 52 is equal in electrical length to the wiring 51. This can prevent the occurrence of a phase shift between a current flowing through the wiring 41 and a current flowing through the wiring 42. This can also prevent the occurrence of a phase shift between a current flowing through the wiring 51 and a current flowing through the wiring 52.

This can prevent the occurrence of cancellation of a magnetic flux as compared to a case in which the wiring 42 is different in electrical length from the wiring 41. This can also prevent the occurrence of cancellation of a magnetic flux as compared to a case in which the wiring 52 is different in electrical length from the wiring 51. In this manner, a decrease of the coupling coefficient k can be prevented. Therefore, the present embodiment can improve the power efficiency of the transformer TR. As the wirings 41 and 42 and the wiring 51 and 52 become greater in length, the magnetic flux cancellation region increases. Therefore, as an operation frequency of the transformer TR decreases, the improvement effect of power efficiency obtained by the transformer TR becomes more significant.

Furthermore, in the present embodiment, the pads Pd1 and Pd2 are each formed into a substantially L shape. The pads Pd3 and Pd4 are each formed into a substantially L shape. This enables an adjustment such that the wiring 42 is equal in electrical length to the wiring 41. This also enables an adjustment such that the wiring 52 is equal in electrical length to the wiring 51.

### 2. Second Embodiment

An isolator according to a second embodiment will be described. An isolator 1A according to the second embodiment differs from that of the first embodiment in terms of a structure of a wiring board 31A. The following description will mainly focus on the portion that differs from the first embodiment.

### 2.1 Structure of Wiring Board

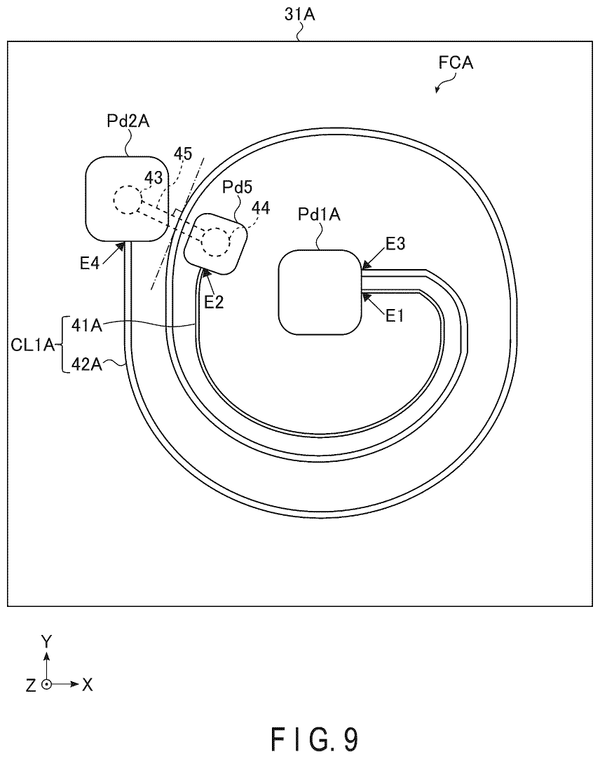

A structure of the wiring board 31A will be described with reference to FIG. 9 to FIG. 14.

FIG. 9 is a planar view showing an example of a planar layout of a primary circuit FCA within the wiring board 31A. As shown in FIG. 9, the wiring board 31A includes pads Pd1A, Pd2A, and Pd5, a coil CL1A, vias 43 and 44, and a wiring 45. FIG. 9 omits illustration of a secondary circuit SCA and the insulating layer within the wiring board 31A.

The pad Pd5 is a member for coupling a wiring 41A and the pad Pd2A with the vias 43 and 44 and the wiring 45 intervening therebetween. The pads Pd1A and Pd2A and Pd5 are formed into, for example, a substantially rectangular shape when viewed from the top. The pad Pd5 is formed of a conductive material.

The first end E1 of the wiring 41A is coupled to the pad Pd1A. The second end E2 of the wiring 41A is coupled to the pad Pd5. The second end E2 is coupled to the pad Pd2A via the pad Pd5, the via 44, the wiring 45, and the via 43. The wiring 41A is formed into, for example, a spiral shape extending from the first end E1 in a clockwise rotation direction to the outside when viewed from the top.

The third end E3 of the wiring 42A is coupled to the pad Pd1A. The fourth end E4 of the wiring 42A is coupled to the pad Pd2A. The wiring 42A is apart from the wiring 41A and is formed into, for example, a spiral shape extending from the third end E3 in a clockwise rotation direction to the outside when viewed from the top.

The via 43 is provided below the pad Pd2A. In other words, the via 43 is in contact with the pad Pd2A. The via 44 is provided below the pad Pd5. In other words, the via 44 is in contact with the pad Pd5. The vias 43 and 44 are formed of a conductive material.

The wiring 45 is a member for coupling the via 43 and the via 44. The wiring 45 is provided below the via 43 and the via 44. In other words, the wiring 45 is in contact with the vias 43 and 44. The wiring 45 is formed of a conductive material.

With the structure described above, the coil CL1A is coupled to the pads Pd1A and Pd2A. More specifically, in the present embodiment, the wirings 41A and 42A are coupled in parallel to each other between the pad Pd1A and the pad Pd2A.

Furthermore, the present embodiment is designed such that the wiring 41A is smaller in thickness than the wiring 42A and the wiring 41A is larger in resistance than the wiring 42A.

Furthermore, the present embodiment is designed such that an electrical length of the wiring 42A is equal to the sum of a length which is N times a wavelength of a current flowing through the wirings 41A and 42A (N is an integer equal to or greater than 1) and an electrical length of the wiring 41A. That is, a relationship between the electrical length of the wiring 42A and the electrical length of the wiring 41A is expressed below by Equation (4). Hereinafter, a length which is N times a wavelength of a current flowing through the wirings 41A and 42A will also be referred to as an “N-fold wavelength”.

$$Electrical Length of Wiring 42 A = N - fold Wavelength + Electrical Length of Wiring 41 A ( N = 1 , 2 , 3 , … ) \qquad ( 4 )$$

Furthermore, in the present embodiment, the wirings 42A and 45 are arranged such that they are apart from each other and perpendicularly intersect each other.

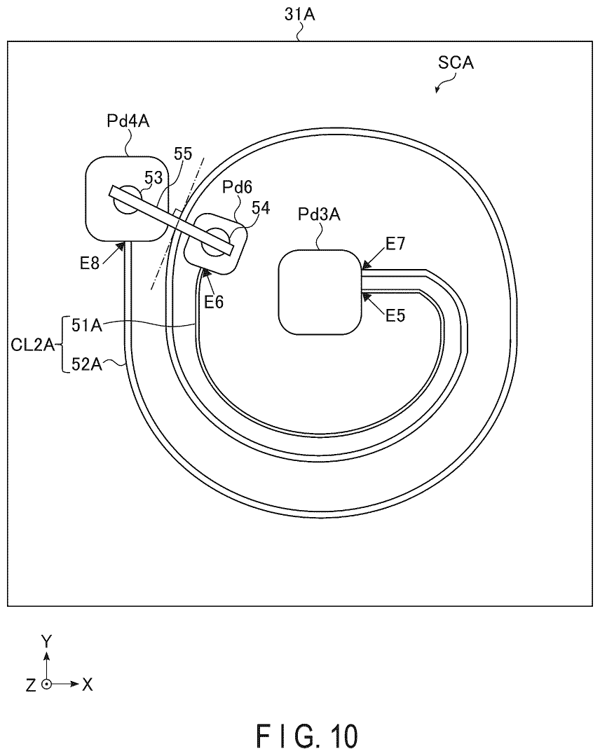

FIG. 10 is a planar view showing an example of a planar layout of the secondary circuit SCA within the wiring board 31A. As shown in FIG. 10, the wiring board 31A includes pads Pd3A, Pd4A, and Pd6, a coil CL2A, vias 53 and 54, and a wiring 55. FIG. 10 omits illustration of a primary circuit FCA and the insulating layer within the wiring board 31A.

The secondary circuit SCA is similar in structure to the primary circuit FCA. Details will be described below.

The pad Pd6 is a member for coupling a wiring 51A and the pad Pd4A via the vias 53 and 54 and the wiring 55. The pads Pd3A, Pd4A, and Pd6 are formed into, for example, a substantially rectangular shape when viewed from the top. The pad Pd6 is formed of a conductive material.

The fifth end E5 of the wiring 51A is coupled to the pad Pd3A. The sixth end E6 of the wiring 51A is coupled to the pad Pd6. The sixth end E6 is coupled to the pad Pd4A via the pad Pd6, the via 54, the wiring 55, and the via 53. The wiring 51A is formed into, for example, a spiral shape extending from the fifth end E5 in a clockwise rotation direction to the outside when viewed from the top.

The seventh end E7 of the wiring 52A is coupled to the pad Pd3A. The eighth end E8 of the wiring 52A is coupled to the pad Pd4A. The wiring 52A is apart from the wiring 51A and is formed into, for example, a spiral shape extending from the seventh end E7 in a clockwise rotation direction to the outside when viewed from the top.

The via 53 is provided on the pad Pd4A. In other words, the via 53 is in contact with the pad Pd4A. The via 54 is provided on the pad Pd6. In other words, the via 54 is in contact with the pad Pd6. The vias 53 and 54 are formed of a conductive material.

The wiring 55 is a member for coupling the via 53 and the via 54. The wiring 55 is provided on the via 53 and the via 54. In other words, the wiring 55 is in contact with the vias 53 and 54. The wiring 55 is formed of a conductive material.

With the structure described above, the coil CL2A is coupled to the pads Pd3A and Pd4A. More specifically, in the present embodiment, the wirings 51A and 52A are coupled in parallel to each other between the pad Pd3A and the pad Pd4A.

Furthermore, the present embodiment is designed such that the wiring 51A is smaller in thickness than the wiring 52A and the wiring 51A is larger in resistance than the wiring 52A.

Furthermore, the present embodiment is designed such that an electrical length of the wiring 52A is equal to the sum of a length which is N times a wavelength of a current flowing through the wirings 51A and 52A (N is an integer equal to or greater than 1) and an electrical length of the wiring 51A. Hereinafter, a length which is N times a wavelength of a current flowing through the wirings 51A and 52A will also be referred to as an “N-fold wavelength”.

Furthermore, in the present embodiment, the wirings 52A and 55 are arranged such that they are apart from each other and perpendicularly intersect each other.

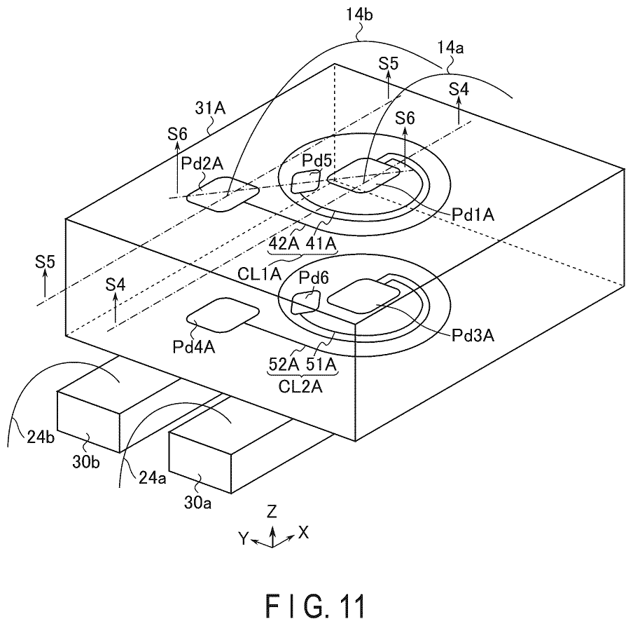

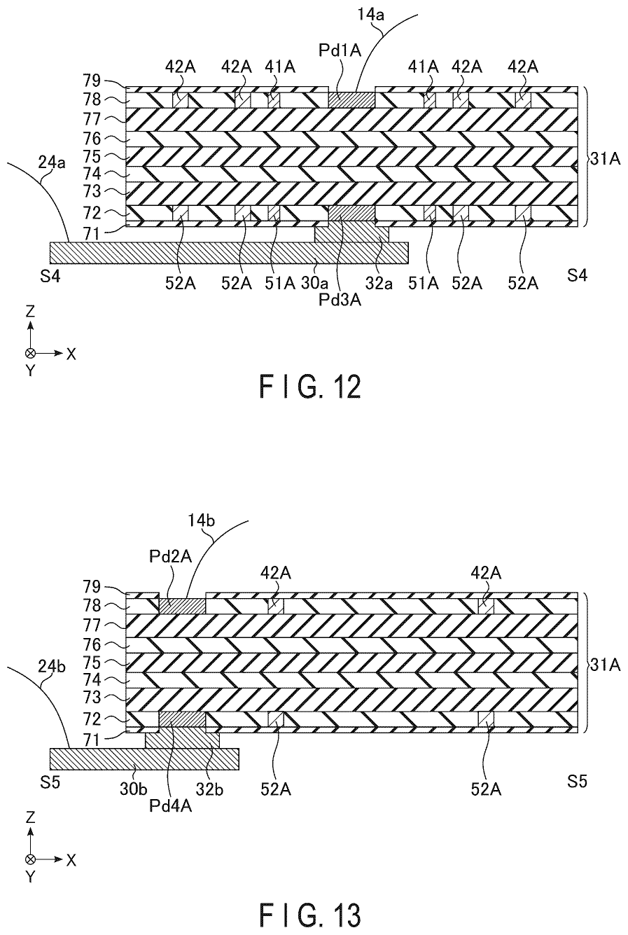

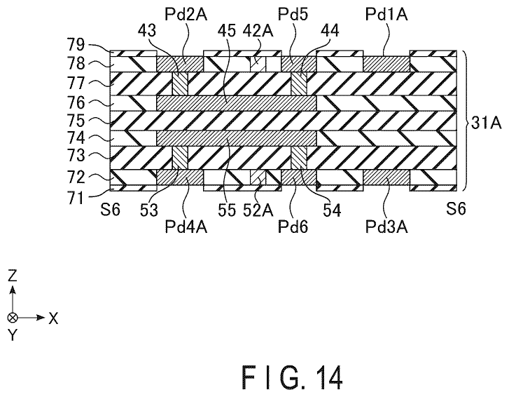

FIG. 11 is a perspective view showing an example of a structure of a wiring board 31A. FIG. 12 is a sectional view taken along line S4-S4 of FIG. 11 and showing an example of a sectional structure of the wiring board 31A. FIG. 13 is a sectional view taken along line S5-S5 of FIG. 11 and showing an example of a sectional structure of the wiring board 31A. FIG. 14 is a sectional view taken along line S6-S6 of FIG. 11 and showing an example of a sectional structure of the wiring board 31A.

As shown in FIG. 11 to FIG. 14, the wiring board 31A includes the pads Pd1A, Pd2A and Pd5, the coil CL1A, the vias 43 and 44, the wiring 45, the pads Pd3A, Pd4A and Pd6, the coil CL2A, the via 53 and 54, the wiring 55, and insulating layers 71 to 79. FIG. 11 to FIG. 13 also show the bonding wires 14a, 14b, 24a, and 24b, the frames 30a and 30b, and the vias 32a and 32b. FIG. 11 omits illustration of the vias 43 and 44, the wiring 45, the vias 53 and 54, the wiring 55, the vias 32a and 32b, and the insulating layers 71 to 79.

As shown in FIG. 11, the coil CL1A is provided above the coil CL2A in the Z direction. That is, the coil CL1A is provided at a position at which it overlaps the coil CL2A in the Z direction. In other words, the coil CL2A is arranged so as to face the coil CL1A with the insulating layers 73 to 77 intervening therebetween. Meanwhile, in the example in FIG. 11, a set of the pads Pd1A, Pd2A, and Pd5, and the coil CL1A, and a set of the pads Pd3A, Pd4A, and Pd6, and the coil CL2A are arranged in alignment with each other. However, these sets may be arranged in a rotating manner with each other. In other words, it suffices that the coil CL1A and the coil CL2A are arranged such that a magnetic flux which penetrates the coil CL1A penetrates the coil CL2A and such that a magnetic flux which penetrates the coil CL2A penetrates the coil CL1A.

The pad Pd1A is coupled to the bonding wire 14a. The pad Pd2A is coupled to the bonding wire 14b. The semiconductor chip 11 is coupled to the coil CL1A via the bonding wires 14a and 14b, the pads Pd1A and Pd2A, the via 43, the wiring 45, the via 44, and the pad Pd5.

The pad Pd3A is coupled to the bonding wire 24a via the via 32a and the frame 30a. The pad Pd4A is coupled to the bonding wire 24b via the via 32b and the frame 30b. The semiconductor chip 21 is coupled to the coil CL2A via the bonding wires 24a and 24b, the frames 30a and 30b, the vias 32a and 32b, the pads Pd3A and Pd4A, the via 53, the wiring 55, the via 54, and the pad Pd6.

As shown in FIG. 12 to FIG. 14, the wiring board 31A has a structure in which the insulating layers 71, 72, 73, 74, 75, 76, 77, 78, and 79 are stacked in this order.

As shown in FIG. 12, the insulating layer 71 includes an opening for coupling the pad Pd3A and the via 32a. The via 32a is provided within the opening of the insulating layer 71 and in the vicinity of the opening on the lower surface of the insulating layer 71.

The insulating layer 72 is provided on the insulating layer 71 and the via 32a. The pad Pd3A and the wirings 51A and 52A (the coil CL2A) are provided within the insulating layer 72. In other words, the pad Pd3A and the wirings 51A and 52A are provided in the same layer. The pad Pd3A is provided on the via 32a. In other words, the pad Pd3A is in contact with the via 32a.

The insulating layer 73 is provided on the insulating layer 72, the pad Pd3A, and the wirings 51A and 52A. The insulating layer 74 is provided on the insulating layer 73. The insulating layer 75 is provided on the insulating layer 74. The insulating layer 76 is provided on the insulating layer 75. The insulating layer 77 is provided on the insulating layer 76.

The insulating layer 78 is provided on the insulating layer 77. The pad Pd1A and the wirings 41A and 42A (the coil CL1A) are provided within the insulating layer 78. In other words, the pad Pd1A and the wirings 41A and 42A are provided in the same layer.

The insulating layer 79 is provided on the insulating layer 78 and the wirings 41A and 42A. The insulating layer 79 includes an opening for coupling the pad Pd1A and the bonding wire 14a. The pad Pd1A is provided below the opening of the insulating layer 79.

As shown in FIG. 13, the insulating layer 71 includes an opening for coupling the pad Pd4A and the via 32b. The via 32b is provided within the opening of the insulating layer 71 and in the vicinity of the opening on the lower surface of the insulating layer 71.

The insulating layer 72 is provided on the insulating layer 71 and the via 32b. The pad Pd4A is provided within the insulating layer 72. In other words, the pad Pd4A is provided in the same layer as the pad Pd3A. The pad Pd4A is provided on the via 32b. In other words, the pad Pd4A is in contact with the via 32b.

The pad Pd2A is provided within the insulating layer 78. In other words, the pad Pd2A is provided in the same layer as the pad Pd1A.

The insulating layer 79 includes an opening for coupling the pad Pd2A and the bonding wire 14b. The pad Pd2A is provided below the opening of the insulating layer 79.

As shown in FIG. 14, the insulating layer 71 includes an opening for exposing the pad Pd6. The pad Pd6 is provided within the insulating layer 72. In other words, the pad Pd6 is provided in the same layer as the pad Pd3A and a Pd4A. The pad Pd6 is provided above the opening of the insulating layer 71.

The vias 53 and 54 are provided within the insulating layer 73. The via 53 is provided on the pad Pd4A. The via 54 is provided on the pad Pd6.

The wiring 55 is provided within the insulating layer 74. The wiring 55 is provided on the via 53 and the via 54.

The insulating layer 79 includes an opening for exposing the pad Pd5. The pad Pd5 is provided within the insulating layer 78. In other words, the pad Pd5 is provided in the same layer as the pad Pd1A and a Pd2A. The pad Pd5 is provided below the opening of the insulating layer 79.

The vias 43 and 44 are provided within the insulating layer 77. The via 43 is provided below the pad Pd2A. The via 44 is provided below the pad Pd5.

The wiring 45 is provided within the insulating layer 76. The wiring 45 is provided below the via 43 and the via 44.

The isolator 1A according to the present embodiment can improve the power efficiency of the transformer TRA.

In the present embodiment, the wirings 41A and 42A are coupled in parallel to each other between the pad Pd1A and the pad Pd2A. In other words, the coil CL1A has a double wiring structure including the wirings 41A and 42A. The wirings 51A and 52A are coupled in parallel to each other between the pad Pd3A and the pad Pd4A. In other words, the coil CL2A has a double wiring structure including the wirings 51A and 52A.

This decreases a combined resistance of the wirings 41A and 42A between the pad Pd1A and the pad Pd2A as compared to a case in which the wirings 41A and 42A are coupled in series between the pad Pd1A and the pad Pd2A. This decreases a combined resistance of the wirings 51A and 52A between the pad Pd3A and the pad Pd4A as compared to a case in which the wirings 51A and 52A are coupled in series between the pad Pd3A and the pad Pd4A.

Accordingly, the Q value of the coil CL1A increases as compared to a case in which the coil CL1A is constituted by a single wiring. The Q value of the coil CL2A increases as compared to a case in which the coil CL2A is constituted by a single wiring. By this, the present embodiment can improve the power efficiency of the transformer TRA.

Furthermore, in the present embodiment, the wiring 41A is smaller in thickness than the wiring 42A and is larger in resistance than the wiring 42A. The wiring 51A is smaller in thickness than the wiring 52A and is larger in resistance than the wiring 52A. This decreases a combined resistance of the wirings 41A and 42A between the pad Pd1A and the pad Pd2A as compared to a case in which the wiring 41A is equal in resistance to the wiring 42A. This decreases a combined resistance of the wirings 51A and 52A between the pad Pd3A and the pad Pd4A as compared to a case in which the wiring 51A is equal in resistance to the wiring 52A.

Accordingly, the Q value of the coil CL1A increases as compared to a case in which the wiring 41A is equal in resistance to the wiring 42A. The Q value of the coil CL2A increases as compared to a case in which the wiring 51A is equal in resistance to the wiring 52A. By this, the present embodiment can improve the power efficiency of the transformer TRA.

Furthermore, in the present embodiment, an electrical length of the wiring 42A is equal to the sum of the N-fold wavelength (N is an integer equal to or greater than 1) and an electrical length of the wiring 41A. An electrical length of the wiring 52A is equal to the sum of the N-fold wavelength (N is an integer equal to or greater than 1) and an electrical length of the wiring 51A. This can prevent the occurrence of a phase shift between a current flowing through the wiring 41A and a current flowing through the wiring 42A. This can also prevent the occurrence of a phase shift between a current flowing through the wiring 51A and a current flowing through the wiring 52A.

This can prevent the occurrence of cancellation of a magnetic flux as compared to a case in which an electrical length of the wiring 42A is different from the sum of the N-fold wavelength (N is an integer equal to or greater than 1) and an electrical length of the wiring 41A. This can prevent the occurrence of cancellation of a magnetic flux as compared to a case in which an electrical length of the wiring 52A is different from the sum of the N-fold wavelength (N is an integer equal to or greater than 1) and an electrical length of the wiring 51A. In this manner, a decrease of the coupling coefficient k can be prevented. Therefore, the present embodiment can improve the power efficiency of the transformer TRA.

Furthermore, in the present embodiment, the wirings 42A and 45 are apart from each other and perpendicularly intersect each other. The wiring 52A and the wiring 55 are apart from each other and perpendicularly intersect each other. By this, a direction of a current flowing through the wiring 42A and a direction of a current flowing through the wirings 45 and 41A are shifted from each other by 90 degrees. A direction of a current flowing through the wiring 52A and a direction of a current flowing through the wirings 55 and 51A are shifted from each other by 90 degrees. Accordingly, a direction of a magnetic flux generated by the current flowing through the wiring 42A and a direction of a magnetic flux generated by the current flowing through the wirings 45 and 41A are shifted from each other by 90 degrees. A direction of a magnetic flux generated by the current flowing through the wiring 52A and a direction of a magnetic flux generated by the current flowing through the wirings 55 and 51A are shifted from each other by 90 degrees.

This can prevent the cancellation of the magnetic flux generated by the current flowing through the wiring 42A and the magnetic flux generated by the current flowing through the wirings 45 and 41A, and the cancellation of the magnetic flux generated by the current flowing through the wiring 52A and the magnetic flux generated by the current flowing through the wirings 55 and 51A. In this manner, a decrease of the coupling coefficient k can be prevented. Therefore, the present embodiment can improve the power efficiency of the transformer TRA.

### 3. Modifications, etc.

As described above, the isolator (1/1A) according to the embodiments includes the first pad (Pd1/Pd1A), the second pad (Pd2/Pd2A), the first coil (CL1/CL1A), the insulating layer (63/73-77), the third pad (Pd3/Pd3A), the fourth pad (Pd4/Pd4A), and the second coil (CL2/CL2A). The first coil (CL1/CL1A) includes the first wiring (41/41A) and the second wiring (42/42A). The first coil (CL1/CL1A) is coupled to the first pad (Pd1/Pd1A) and the second pad (Pd2/Pd2A). The second coil (CL2/CL2A) includes the third wiring (51/51A) and the fourth wiring (52/52A). The second coil (CL2/CL2A) is arranged so as to face the first coil (CL1/CL1A) with the insulating layer (63/73-77) intervening therebetween. The second coil (CL2/CL2A) is coupled to the third pad (Pd3/Pd3A) and the fourth pad (Pd4/Pd4A). The first wiring (41/41A) and the second wiring (42/42A) are coupled in parallel to each other between the first pad (Pd1/Pd1A) and the second pad (Pd2/Pd2A). The third wiring (51/51A) and the fourth wiring (52/52A) are coupled in parallel to each other between the third pad (Pd3/Pd3A) and the fourth pad (Pd4/Pd4A).

The embodiments are not limited to those described in the above, and various modifications can be made.

### 3.1 Modification of Second Embodiment

An isolator according to a modification of the second embodiment will be described. An isolator 1B according to the modification of the second embodiment differs from that of the second embodiment in terms of a structure of a wiring board 31B and in that the vias 32a and 32b and the frames 30a and 30b are eliminated. The following description will mainly focus on the configurations that differ from the second embodiment.

### 3.1.1 Structure of Isolator

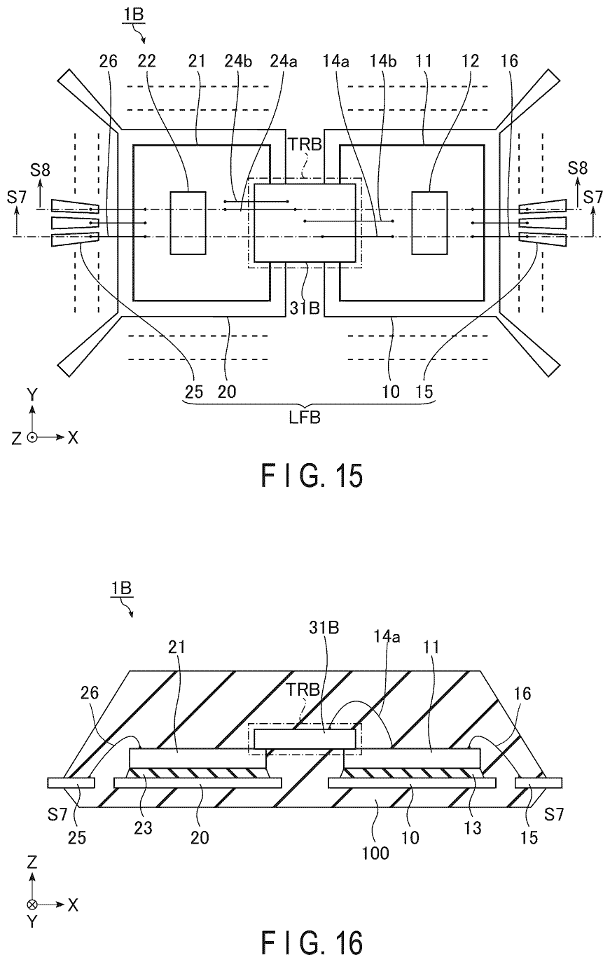

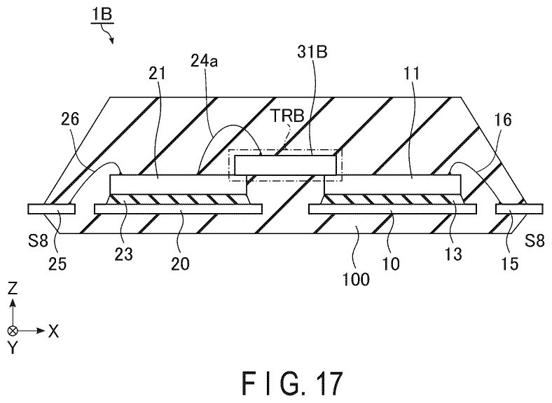

A structure of the isolator 1B will be described with reference to FIG. 15 to FIG. 17. FIG. 15 is a planar view showing an example of a planar layout of the isolator 1B. FIG. 16 is a sectional view taken along line S7-S7 of FIG. 15 and showing an example of a sectional structure of the isolator 1B. FIG. 17 is a sectional view taken along line S8-S8 of FIG. 15 and showing an example of a sectional structure of the isolator 1B.

As shown in FIG. 15 to FIG. 17, the isolator 1B includes the die pads 10 and 20, the semiconductor chips 11 and 21, the leads 15 and 25, a transformer TRB, and the insulating member 100. Meanwhile, FIG. 15 omits illustration of the insulating member 100.

The die pads 10 and 20 and the leads 15 and 25 constitute a lead frame. Hereinafter, a combination of the die pads 10 and 20 and the leads 15 and 25 will be referred to as a “lead frame LFB”.

As shown in FIG. 15, the wiring board 31B is arranged on the semiconductor chips 11 and 21. The die pads 10 and 20, the semiconductor chips 11 and 21, the bonding wires 14a, 14b, 16, 24a, 24b, and 26, and the wiring board 31B are sealed with the insulating member 100.

As shown in FIG. 16, one end of the lower surface of the wiring board 31B is provided on the semiconductor chip 11. The other end of the lower surface of the wiring board 31B is provided on the semiconductor chip 21.

As shown in FIG. 17, one end of the bonding wire 24a is provided on the semiconductor chip 21. The other end of the bonding wire 24a is provided on the wiring board 31B.

### 3.1.2 Structure of Wiring Board

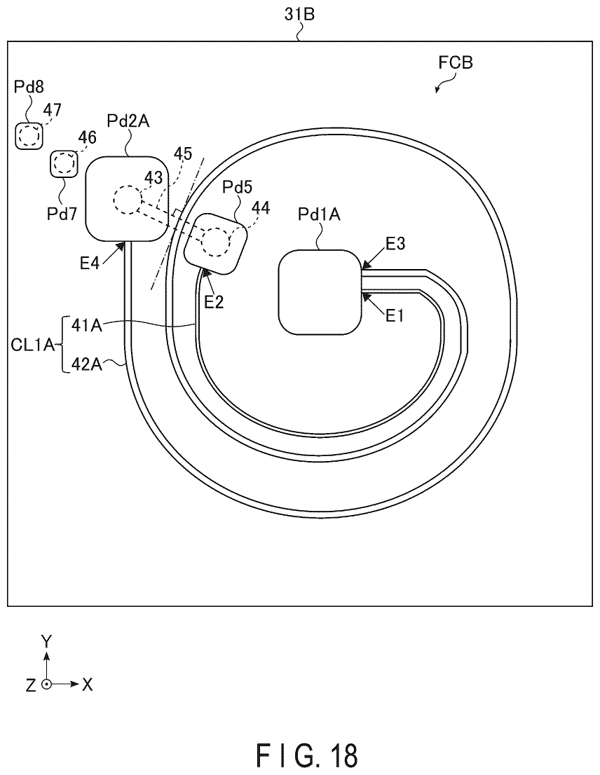

A structure of the wiring board 31B will be described with reference to FIG. 18 to FIG. 23.

FIG. 18 is a planar view showing an example of a planar layout of a primary circuit FCB within the wiring board 31B. As shown in FIG. 18, the wiring board 31B includes the pads Pd1A, Pd2A, Pd5, Pd7, and Pd8, the coil CL1A, the vias 43, 44, 46, and 47, and the wiring 45. FIG. 18 omits illustration of a secondary circuit SCB and the insulating layer within the wiring board 31B.

The pad Pd7 is a member for coupling the coil CL2A and the bonding wire 24a. The pad Pd8 is a member for coupling the coil CL2A and the bonding wire 24b. The pads Pd7 and Pd8 are each formed into, for example, a substantially rectangular shape when viewed from the top. The pads Pd7 and Pd8 are formed of a conductive material.

The via 46 is provided below the pad Pd7. In other words, the via 46 is in contact with the pad Pd7. The via 47 is provided below the via pad Pd8. In other words, the via 47 is in contact with the pad Pd8. The vias 46 and 47 are formed of a conductive material.

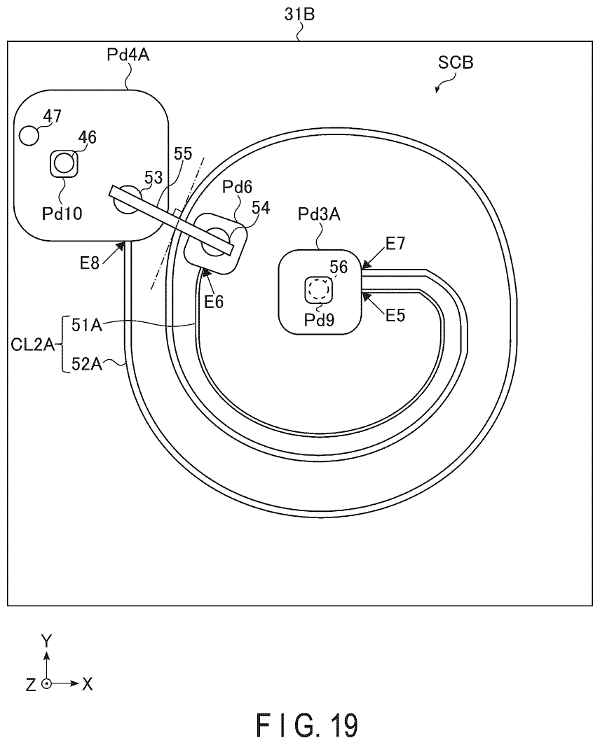

FIG. 19 is a planar view showing an example of a planar layout of the secondary circuit SCB within the wiring board 31B. As shown in FIG. 19, the wiring board 31B includes the pads Pd3A, Pd4A, Pd6, Pd9, and Pd10, the coil CL2A, the vias 46, 47, 53, 54, and 56, and the wiring 55. FIG. 19 omits illustration of the primary circuit FCB and the insulating layer within the wiring board 31B.

The pads Pd9 and Pd10 are members for coupling the pad Pd3A and the pad Pd7. The pad Pd9 is provided above the pad Pd3A. The pad Pd10 is provided above the pad Pd4A. The pads Pd9 and Pd10 are each formed into, for example, a substantially rectangular shape when viewed from the top. The pads Pd9 and Pd10 are formed of a conductive material.

The via 46 is provided on the pad Pd10. In other words, the via 46 is in contact with the pad Pd10. The via 47 is provided on the pad Pd4A. In other words, the via 47 is in contact with the pad Pd4A. The via 56 is provided on the pad Pd3A. The via 56 is provided below the pad Pd9. In other words, the via 56 is in contact with the pads Pd3A and Pd9. The via 56 is formed of a conductive material.

The pad Pd3A and the coil CL2A are similar in structure to those of the second embodiment shown in FIG. 10. The pad Pd4A is similar in structure to that shown in FIG. 10 except that the pad Pd4A is larger in size than that shown in FIG. 10.

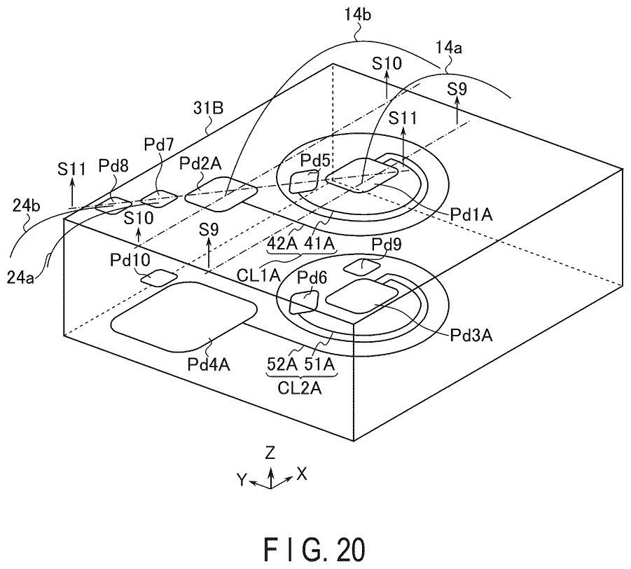

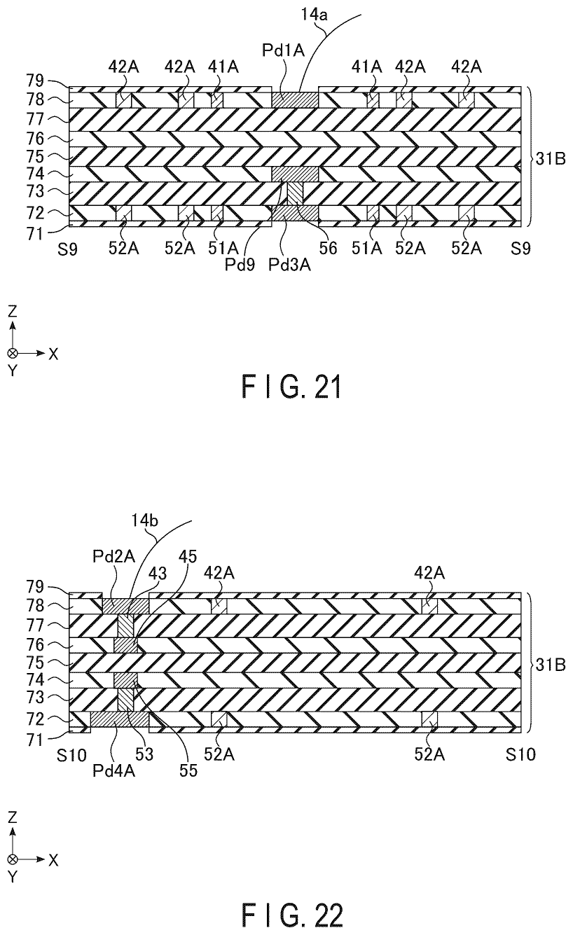

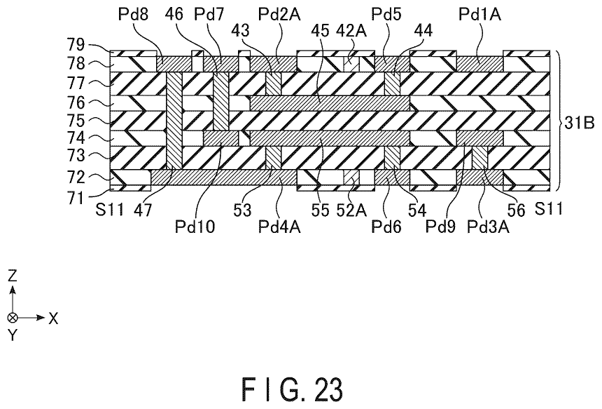

FIG. 20 is a perspective view showing an example of the structure of the wiring board 31B. FIG. 21 is a sectional view taken along line S9-S9 of FIG. 20 and showing an example of a sectional structure of the wiring board 31B. FIG. 22 is a sectional view taken along line S10-S10 of FIG. 20 and showing an example of a sectional structure of the wiring board 31B. FIG. 23 is a sectional view taken along line S11-S11 of FIG. 20 and showing an example of a sectional structure of the wiring board 31B.

As shown in FIG. 20 to FIG. 23, the wiring board 31B includes the pads Pd1A, Pd2A, Pd5, Pd7, and Pd8, the coil CL1A, the vias 43, 44, 46, and 47, the wiring 45, the pads Pd3A, Pd4A, Pd6, Pd9 and Pd10, the coil CL2A, the vias 53, 54, and 56, the wiring 55, and the insulating layers 71 to 79. FIG. 20 to FIG. 22 also show the bonding wires 14a, 14b, 24a, and 24b. FIG. 20 omits illustration of the insulating layers 71 to 79.

As shown in FIG. 20, the pad Pd7 is coupled to the bonding wire 24a. The pad Pd8 is coupled to the bonding wire 24b.

As shown in FIG. 21, the via 56 is provided within the insulating layer 73. The via 56 is provided on the pad Pd3A.

The pad Pd9 is provided within the insulating layer 74. The pad Pd9 is provided on the via 56.

As shown in FIG. 22, the via 53 is provided within the insulating layer 73. The via 53 is provided on the pad Pd4A.

The wiring 55 is provided within the insulating layer 74. The wiring 55 is provided on the via 53.

The via 43 is provided within the insulating layer 77. The via 43 is provided below the pad Pd2A.

The wiring 45 is provided within the insulating layer 76. The wiring 45 is provided below the via 43.

As shown in FIG. 23, the pad Pd10 is provided within the insulating layer 74. The pad Pd10 and the pad Pd9 are electrically coupled together. The via 46 penetrates the insulating layers 75 to 77. The via 46 is provided on the pad Pd10. The via 46 is provided below the via pad Pd7. In other words, the via 46 is in contact with the pads Pd7 and Pd10. The via 47 penetrates the insulating layers 73 to 77. The via 47 is provided on the pad Pd4A. The via 47 is provided below the pad Pd8. In other words, the via 47 is in contact with the pads Pd4A and Pd8.

As with the second embodiment, the isolator 1B according to the present modification can improve the power efficiency of the transformer TRB.

### 3.2 Modification of First Embodiment

An isolator according to a modification of the first embodiment will be described. An isolator 1C according to the modification of the first embodiment differs from that of the first embodiment in terms of a structure of a wiring board 31C and in that the vias 32a and 32b and the frames 30a and 30b are eliminated. The following description will mainly focus on the configurations that differ from the first embodiment.

### 3.2.1 Structure of Isolator

The isolator 1C is similar in structure to that of the second embodiment shown in FIG. 15 to FIG. 17.

### 3.2.2 Structure of Wiring Board

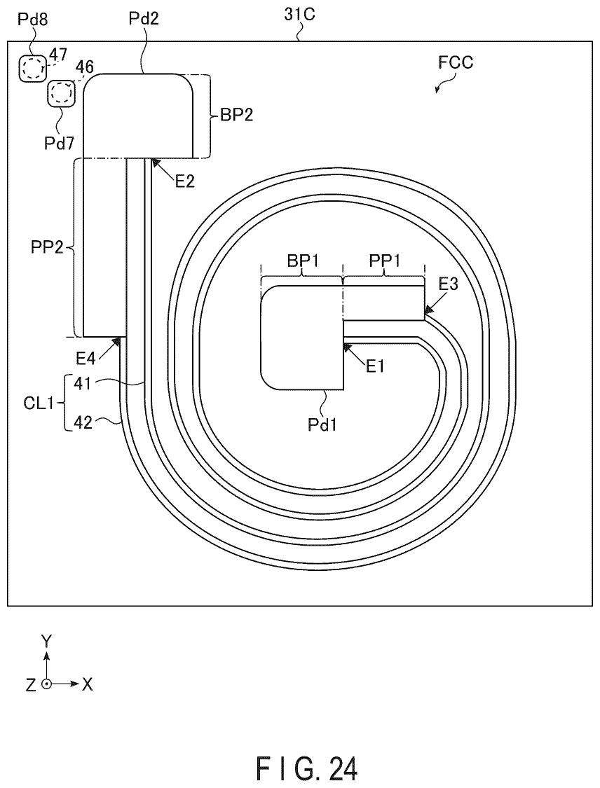

A structure of the wiring board 31C will be described with reference to FIG. 24 to FIG. 29.

FIG. 24 is a planar view showing an example of a planar layout of a primary circuit FCC within the wiring board 31C. As shown in FIG. 24, the wiring board 31C includes the pads Pd1, Pd2, Pd7, and Pd8, the coil CL1, and the vias 46 and 47. FIG. 24 omits illustration of a secondary circuit SCC and the insulating layer within the wiring board 31C.

The pad Pd7 is a member for coupling the coil CL2 and the bonding wire 24a. The pad Pd8 is a member for coupling the coil CL2 and the bonding wire 24b. The pads Pd7 and Pd8 are each formed into, for example, a substantially rectangular shape when viewed from the top. The pads Pd7 and Pd8 are formed of a conductive material.

The via 46 is provided below the pad Pd7. In other words, the via 46 is in contact with the pad Pd7. The via 47 is provided below the pad Pd8. In other words, the via 47 is in contact with the pad Pd8. The vias 46 and 47 are formed of a conductive material.

The pads Pd1 and Pd2 and the coil CL1 are similar in structure to those of the first embodiment shown in FIG. 3.

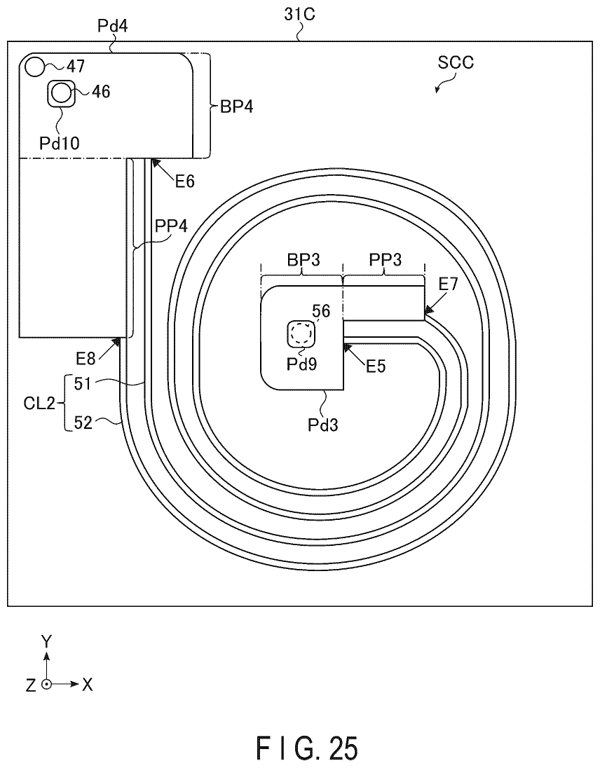

FIG. 25 is a planar view showing an example of a planar layout of the secondary circuit SCC within the wiring board 31C. As shown in FIG. 25, the wiring board 31C includes the pads Pd3, Pd4, Pd9, and Pd10, the coil CL2, and the vias 46, 47 and 56. FIG. 25 omits illustration of the primary circuit FCC and the insulating layer within the wiring board 31C.

The pads Pd9 and Pd10 are members for coupling the pad Pd3 and the pad Pd7. The pad Pd9 is provided above the pad Pd3. The pad Pd10 is provided above the pad Pd4. The pads Pd9 and Pd10 are each formed into, for example, a substantially rectangular shape when viewed from the top. The pads Pd9 and Pd10 are formed of a conductive material.

The via 46 is provided on the pad Pd10. In other words, the via 46 is in contact with the pad Pd10. The via 47 is provided on the pad Pd4. In other words, the via 47 is in contact with the pad Pd4. The via 56 is provided on the pad Pd3. The via 56 is provided below the pad Pd9. In other words, the via 56 is in contact with the pads Pd3 and Pd9. The via 56 is formed of a conductive material.

The pad Pd3 and the coil CL2 are similar in structure to those of the first embodiment shown in FIG. 5. The pad Pd4 is similar in structure to that shown in FIG. 5 except that the pad Pd4 is larger in size than that shown in FIG. 5.

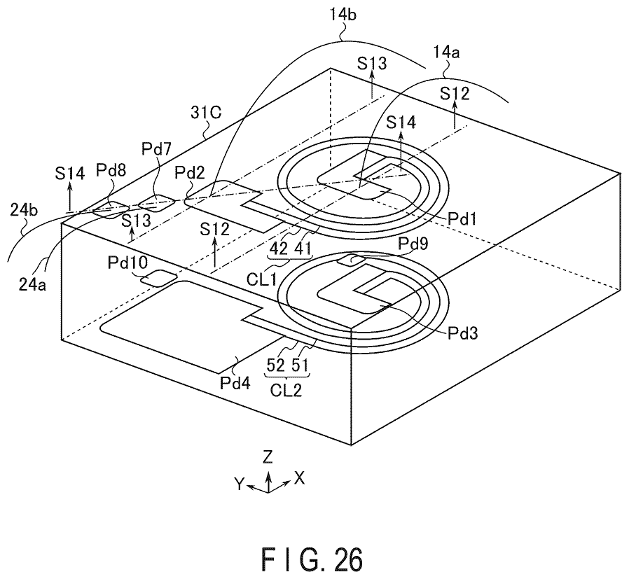

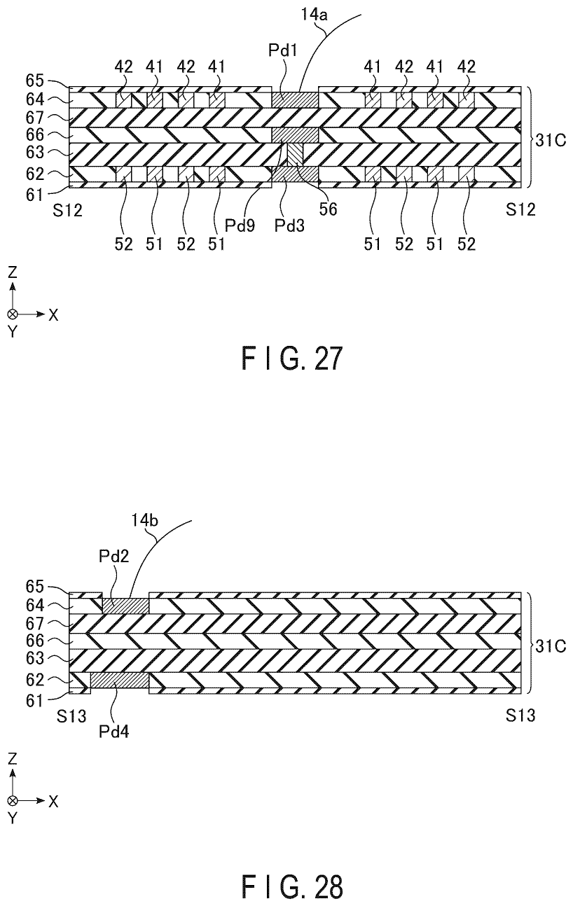

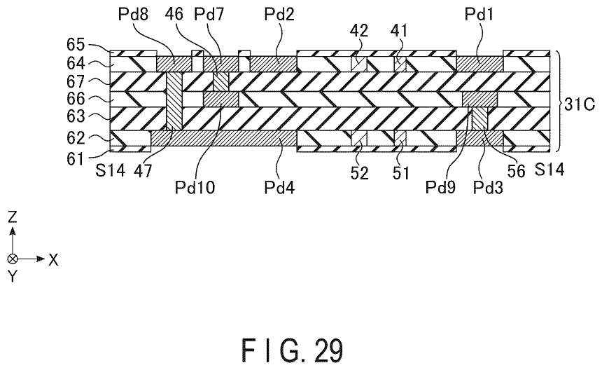

FIG. 26 is a perspective view showing an example of the structure of the wiring board 31C. FIG. 27 is a sectional view taken along line S12-S12 of FIG. 26 and showing an example of a sectional structure of the wiring board 31C. FIG. 28 is a sectional view taken along line S13-S13 of FIG. 26 and showing an example of a sectional structure of the wiring board 31C. FIG. 29 is a sectional view taken along line S14-S14 of FIG. 26 and showing an example of a sectional structure of the wiring board 31C.

As shown in FIG. 26 to FIG. 29, the wiring board 31C includes the pads Pd1, Pd2, Pd7, and Pd8, the coil CL1, the vias 46 and 47, the pads Pd3, Pd4, Pd9, and Pd10, the coil CL2, the via 56, and the insulating layers 61 to 67. FIG. 26 to FIG. 28 also show the bonding wires 14a, 14b, 24a, and 24b. FIG. 26 omits illustration of the insulating layers 61 to 67.

As shown in FIG. 26, the pad Pd7 is coupled to the bonding wire 24a. The pad Pd8 is coupled to the bonding wire 24b.

As shown in FIG. 27 to FIG. 29, the wiring board 31C has a structure in which the insulating layers 61, 62, 63, 66, 67, 64, and 65 are stacked in this order. In other words, the wiring board 31C has a structure in which the insulating layers 66 and 67 are provided between the insulating layer 63 and the insulating layer 64 shown in FIG. 7 and FIG. 8 describing the first embodiment.

As shown in FIG. 27, the via 56 is provided within the insulating layer 63. The via 56 is provided on the pad Pd3.

The insulating layer 66 is provided on the insulating layer 63. The insulating layer 67 is provided on the insulating layer 66. The insulating layer 64 is provided on the insulating layer 67.

The pad Pd9 is provided within the insulating layer 66. The pad Pd9 is provided on the via 56.

As shown in FIG. 28, the pad Pd4 is larger in size than the pad Pd2.

As shown in FIG. 29, the pad Pd10 is provided within the insulating layer 66. The pad Pd10 and the pad Pd9 are electrically coupled together. The via 46 is provided within the insulating layer 67. The via 46 is provided on the pad Pd10. The via 46 is provided below the pad Pd7. In other words, the via 46 is in contact with the pads Pd7 and Pd10. The via 47 penetrates the insulating layers 63, 66, and 67. The via 47 is provided on the pad Pd4. The via 47 is provided below the pad Pd8. In other words, the via 47 is in contact with the pads Pd4 and Pd8.

As with the first embodiment, the isolator 1C according to the present modification can improve the power efficiency of the transformer TRC.

The embodiments and modifications described above are applicable to isolators of two or more channels.

Throughout the specification, the expression “coupling” refers to electrical coupling and does not exclude, for example, interposition of another element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An isolator comprising:
a first pad;
a second pad;
a first coil including a first wiring and a second wiring and coupled to the first pad and the second pad;
an insulating layer;
a third pad;
a fourth pad; and
a second coil including a third wiring and a fourth wiring, arranged to face the first coil with the insulating layer intervening between the second coil and the first coil, and coupled to the third pad and the fourth pad,
wherein the first wiring and the second wiring are coupled in parallel to each other between the first pad and the second pad, and
the third wiring and the fourth wiring are coupled in parallel to each other between the third pad and the fourth pad.

2. The isolator according to claim 1, wherein an electrical length of the second wiring is equal to an electrical length of the first wiring, and
an electrical length of the fourth wiring is equal to an electrical length of the third wiring.

3. The isolator according to claim 2, wherein the first pad includes a first base portion and a first projection portion projecting from the first base portion in a first direction,
the second pad includes a second base portion and a second projection portion projecting from the second base portion in a second direction intersecting the first direction,
the first wiring includes a first end coupled to the first base portion of the first pad and a second end coupled to the second base portion of the second pad,
the second wiring includes a third end coupled to the first projection portion of the first pad and a fourth end coupled to the second projection portion of the second pad,
the third pad includes a third base portion and a third projection portion projecting from the third base portion in the first direction,
the fourth pad includes a fourth base portion and a fourth projection portion projecting from the fourth base portion in the second direction,
the third wiring includes a fifth end coupled to the third base portion of the third pad and a sixth end coupled to the fourth base portion of the fourth pad, and
the fourth wiring includes a seventh end coupled to the third projection portion of the third pad and an eighth end coupled to the fourth projection portion of the fourth pad.

4. The isolator according to claim 3, wherein the first wiring is formed into a spiral shape extending from the first end in a first rotation direction to an outside when viewed from a top,
the second wiring is apart from the first wiring and is formed into a spiral shape extending from the third end in the first rotation direction to the outside when viewed from the top,
the third wiring is formed into a spiral shape extending from the fifth end in the first rotation direction to the outside when viewed from the top, and
the fourth wiring is apart from the third wiring and is formed into a spiral shape extending from the seventh end in the first rotation direction to the outside when viewed from the top.

5. The isolator according to claim 4, wherein the spiral shape of the first wiring, the spiral shape of the second wiring, the spiral shape of the third wiring, and the spiral shape of the fourth wiring are each an ellipsoidal shape.

6. The isolator according to claim 4, wherein an outer diameter of the first coil in the second direction is greater than an outer diameter of the first coil in the first direction, and
an outer diameter of the second coil in the second direction is greater than an outer diameter of the second coil in the first direction.

7. The isolator according to claim 4, wherein in the second direction, a total number of turns in the first wiring and the second wiring on a side close to the second pad with respect to the first pad is smaller than a total number of turns in the first wiring and the second wiring on an opposite side to the second pad with respect to the first pad, and
in the second direction, a total number of turns in the third wiring and the fourth wiring on a side close to the fourth pad with respect to the third pad is smaller than a total number of turns in the third wiring and the fourth wiring on an opposite side to the fourth pad with respect to the third pad.

8. The isolator according to claim 1, wherein an electrical length of the second wiring is equal to a sum of a length which is N times a wavelength of a current flowing through the first wiring and the second wiring (where N is an integer equal to or greater than 1) and an electrical length of the first wiring, and
an electrical length of the fourth wiring is equal to a sum of a length which is N times a wavelength of a current flowing through the third wiring and the fourth wiring (where N is an integer equal to or greater than 1) and an electrical length of the third wiring.

9. The isolator according to claim 8, further comprising:
a fifth pad;
a fifth wiring;
a sixth pad; and
a sixth wiring,
wherein the first wiring includes a first end coupled to the first pad and a second end coupled to the second pad,
the second wiring includes a third end coupled to the first pad and a fourth end coupled to the second pad,
the second end of the first wiring is coupled to the second pad via the fifth pad and the fifth wiring,
the second wiring and the fifth wiring are apart from each other and perpendicularly intersect each other,
the third wiring includes a fifth end coupled to the third pad and a sixth end coupled to the fourth pad,
the fourth wiring includes a seventh end coupled to the third pad and an eighth end coupled to the fourth pad,
the sixth end of the third wiring is coupled to the fourth pad via the sixth pad and the sixth wiring, and
the fourth wiring and the sixth wiring are apart from each other and perpendicularly intersect each other.

10. The isolator according to claim 9, wherein the first wiring is formed into a spiral shape extending from the first end in a first rotation direction to an outside when viewed from a top,
the second wiring is apart from the first wiring and is formed into a spiral shape extending from the third end in the first rotation direction to the outside when viewed from the top,
the third wiring is formed into a spiral shape extending from the fifth end in the first rotation direction to the outside when viewed from the top, and
the fourth wiring is apart from the third wiring and is formed into a spiral shape extending from the seventh end in the first rotation direction to the outside when viewed from the top.

11. The isolator according to claim 10, wherein the spiral shape of the first wiring, the spiral shape of the second wiring, the spiral shape of the third wiring, and the spiral shape of the fourth wiring are each an ellipsoidal shape.

12. The isolator according to claim 8, wherein a thickness of the first wiring is smaller than a thickness of the second wiring, and
a thickness of the third wiring is smaller than a thickness of the fourth wiring.

13. The isolator according to claim 1, wherein the second wiring is provided in a same layer as the first wiring, and
the fourth wiring is provided in a same layer as the third wiring.

14. The isolator according to claim 13, wherein the first pad is provided in a same layer as the first wiring and the second wiring, and
the third pad is provided in a same layer as the third wiring and the fourth wiring.

15. The isolator according to claim 14, wherein the second pad is provided in a same layer as the first pad, and
the fourth pad is provided in a same layer as the third pad.

16. The isolator according to claim 1, further comprising:
a first semiconductor chip coupled to the first coil via the first pad and the second pad; and
a second semiconductor chip coupled to the second coil via the third pad and the fourth pad.
